(19) United States
(12) Patent Application Publication
(10) Pub. No.: US 2022/0314543 A1
(43) Pub. Date: Oct. 6, 2022

(54) 3D PRINTING METHOD AND SYSTEM USING NEAR-INFRARED SEMICONDUCTOR LASER AS HEATING SOURCE

(71) Applicant: INSTITUTE OF CHEMISTRY, CHINESE ACADEMY OF SCIENCES, Beijing (CN)

(72) Inventors: Weizhi ZOU, Beijing (CN); Jian XU, Beijing (CN); Zhiyan ZHANG, Beijing (CN); Yan GAO, Beijing (CN); Xuechun LIN, Beijing (CN); Ning ZHAO, Beijing (CN)

(21) Appl. No.: 17/597,010

(22) PCT Filed: Mar. 29, 2021
(86) PCT No.: PCT/CN2021/083619

§ 371 Date: Dec. 22, 2021

(30) Foreign Application Priority Data
Apr. 7, 2020 (CN) 202010266315.6

(51) Int. Cl. B29C 64/268; B33Y 10/00; B33Y 30/00

(52) U.S. Cl. CPC B29C 64/268; B33Y 10/00; B33Y 30/00

(57) ABSTRACT

Provided is a 3D printing method and system using a near-infrared semiconductor laser as a heating source. The 3D printing system includes a printing spray head (4). In the 3D printing process, a laser beam is output by the near-infrared semiconductor laser to form a laser spot, which scans in an arbitrary path to cover a relevant area of a printed material for in-situ heating, thereby realizing the “asynchronous” printing mode. The near-infrared laser has higher penetration depth compared with a mid-infrared laser, so that the printing method using a near-infrared semiconductor laser as a heating source can be flexibly compatible with various printing platforms and the working process of the laser in the formed printing system can be decoupled from the 3D printing process of an article.

The present application claims priority to Chinese Patent No. 202010266315.6 filed with China National Intellectual Property Administration on Apr. 7, 2020 and entitled “3D PRINTING METHOD AND PRINTING SYSTEM USING NEAR-INFRARED SEMICONDUCTOR LASER AS HEATING SOURCE”, which is incorporated herein by reference in its entirety.

### TECHNICAL FIELD

The present invention relates to the field of 3D printing, and in particular to a 3D printing method and printing system using a near-infrared semiconductor laser as a heating source.

### BACKGROUND

3D printing is an emerging rapid-prototyping technology that converts a virtual 3D model of computer aided design (CAD) into a physical object constructed from a polymer material, and is regarded as a symbol of the third industrial revolution. After years of development, 3D printing technology has been widely used in the fields of scientific research, education, medical treatment, aerospace and the like, and the implementation means thereof include photopolymerization 3D printing, powder bed selective laser sintering (SLS) 3D printing, jet printing, fused deposition modeling (FDM) 3D printing and the like. In SLS and FDM, the use of laser as the heating source is a universal, efficient and simple method for fusing and sintering polymer powder or reheating extruded filaments of polymer to achieve high-quality casting of articles. The laser heating source reported so far is mainly a far-infrared CO₂ gas laser with a laser wavelength of 10.6 However, the CO₂ gas laser has the disadvantages of large volume, few adjustable laser parameters, poor flexibility and easy damage of the matching transmission optical fiber, and the like, which make it unable to be flexibly loaded on commercial desktop 3D printers and large industrial 3D printers, which limits the processing scope for improving the mechanical properties of 3D printed articles.

### SUMMARY

In order to overcome the defects of the existing CO₂ gas laser as a heating source in the 3D printing process, the present invention provides a 3D printing method in which a near-infrared semiconductor laser is used as the heating source.

A semiconductor laser employs, as working substance, semiconductor materials such as gallium arsenide (GaAs), indium phosphide (InP) and compounds thereof, and outputs laser beams under electric injection, electron beam excitation and optical pumping modes. A semiconductor laser has excellent characteristics such as wide wavelength range of coverage, output power of up to kilowatt, high conversion efficiency, high reliability, long service life, small device size, high flexibility of transmission optical fiber and the like, which make it become the most widely used laser at present. In addition to the above-mentioned common characteristics of the semiconductor lasers, the near-infrared semiconductor laser has an output of laser wavelength of 0.78-2.5 which is in the near-infrared band of 0.75-3 μm and thus is different from the far-infrared wavelength of 10.6 μm output by the CO₂ gas laser. Furthermore, the absorption at 0.78-2.5 μm wavelength is weaker for almost all polymer materials, because the absorption is mainly generated at this wavelength by sum-frequency vibration and multiple frequency vibration of material molecules. Therefore, the near-infrared laser has higher penetration depth, which is more beneficial to synchronous heat treatment on multi-layer materials in the 3D printing process and has better elimination of the defects of 3D printed articles. This is not possible with the CO₂ laser, since the CO₂ laser can only perform surface cladding. The interaction between the near-infrared wavelength and the polymer molecules is weaker than the absorption effect of the vibration of covalent bonds such as C—H, C—O, C—N, O—H, N—H of polymer molecules on the far-infrared wavelength of 10.6 Therefore, the near-infrared laser has higher penetration depth on the polymer material, and can simultaneously solve the weak interface bonding strength of multilayer extruded filaments or sintered powder and the defects of the mechanical property and the structure of an article such as warping deformation caused by residual internal stress. In addition, compared with the CO₂ gas laser, the near-infrared semiconductor laser is cost-efficient and time-saving, and can be transmitted by a flexible optical fiber (such as a quartz optical fiber), which greatly improves its application range and feasibility.

Based on the above-mentioned findings, a 3D printing method using a near-infrared semiconductor laser as a heating source is provided. As described above, the near-infrared semiconductor laser, as a heating source, has higher penetration depth, and does not need to process the single-layer printing surfaces one by one for layer-by-layer bonding by a CO₂ gas laser capable of generating a far-infrared wavelength of 10.6 so that it can simultaneously solve the weak interface bonding strength of multilayer extruded filaments or sintered powder and the defects of the mechanical property and the structure of an article such as warping deformation caused by residual internal stress; the near-infrared semiconductor laser and the printing head can be in a “same-track asynchronous” printing mode or a “double-track asynchronous” printing mode, and a laser stepping control device used in the method is decoupled from a printing stepping device, that is, the laser can scan a printed article with a movement track different from a printing path after single-layer or multi-layer printing, and then the heat treatment is performed. The near-infrared semiconductor laser has the characteristics of high compatibility of printing platforms, wide application range of materials, low preparation cost and the like.

The purpose of the present invention is achieved by providing:

a 3D printing method in which a near-infrared semiconductor laser is used as a heating source, that is, a laser beam generated by the laser is used for in-situ heating of an article in the 3D printing process.

According to the present invention, the method employs a 3D printing device using a near-infrared semiconductor laser as a heating source to perform the 3D printing in an “asynchronous” mode.

Specifically, the 3D printing device comprises a printing head; in the 3D printing process, a laser beam (such as a collimated beam) is output by the near-infrared semiconductor laser to form a laser spot, which scans in an arbitrary path to cover a relevant area of a printed material for in-situ heating, thereby realizing the “asynchronous” printing mode.

In the present invention, the laser output by the near-infrared semiconductor laser realizes flexible optical fiber transmission through spatial coupling; the near-infrared semiconductor laser comprises a flexible optical fiber and an optical fiber head beam shaping system, wherein the optical fiber head beam shaping system comprises a beam collimating mirror and an adjustable attenuator, and the laser output by the near-infrared semiconductor laser realizes flexible optical fiber transmission through spatial coupling, and a collimated beam is output through the beam collimating mirror and the adjustable attenuator to form a laser spot, which is adjustable in size and shape, homogeneous in power and collimated and shows no change of optical power with distance.

According to the present invention, the method comprises:

performing 3D printing by using a 3D printing device with the near-infrared semiconductor laser as the heating source, wherein in the printing process, the laser output by the near-infrared semiconductor laser realizes flexible optical fiber transmission through spatial coupling, and a collimated beam is output through an optical fiber head beam shaping system of the near-infrared semiconductor laser to form a laser spot, which scans in an arbitrary path to cover a relevant area of the printed material for in-situ heating of an article, thereby realizing “asynchronous” printing mode in the 3D printing process.

Specifically, the method comprises:

performing 3D printing by using a 3D printing device with the near-infrared semiconductor laser as the heating source, wherein in the printing process, the near-infrared semiconductor laser and a printing head are separately controlled by double tracks, and the printing head is used to print single-layer or multi-layer materials (such as extrusion printing, jet printing or selective sintering printing). The laser output by the near-infrared semiconductor laser realizes flexible optical fiber transmission through spatial coupling, and a collimated beam is output by an optical fiber head beam shaping system of the near-infrared semiconductor laser to form a laser spot, which scans in an arbitrary path to cover a relevant area of the printed material for in-situ heating. The process is repeated for multiple times to realize “double-track asynchronous” printing mode of an article in the 3D printing process.

Specifically, the method comprises:

performing 3D printing by using a 3D printing device with the near-infrared semiconductor laser as the heating source, wherein in the printing process, the near-infrared semiconductor laser and a printing head are controlled by the same track, and first the printing head is used to print single-layer or multi-layer materials (such as extrusion printing, jet printing or selective sintering printing) (step one); then the printing is suspended, and the laser output by the near-infrared semiconductor laser realizes flexible optical fiber transmission through spatial coupling, and a collimated beam is output by an optical fiber head beam shaping system of the near-infrared semiconductor laser to form a laser spot, which scans in an arbitrary path to cover a relevant area of the printed material for in-situ heating (step two). The two steps are repeated for multiple times to realize “same-track asynchronous” printing mode of an article in the 3D printing process.

In the method, the thickness of the single-layer or multi-layer materials is, for example, 0.1-1 mm.

In the method, the printing head may be a printing spray head (such as an extrusion type printing spray head, a jet type printing spray head) or a laser-sintering printing head.

In the method, in the “same-track asynchronous” printing mode, the laser spot is irradiated at a certain angle to the discharge deposition position of the printing spray head or the laser focusing position of the laser-sintering printing head.

In the method, in the “double-track asynchronous” printing mode, the irradiation angle of the laser spot and the discharge deposition position of the printing spray head or the laser focusing position of the laser-sintering printing head are not specially defined.

In the present invention, in the printing process, the output power and the size of the laser spot can be adjusted in real time along with the physical and chemical properties of the printed material (including glass transition temperature T_{g}, melting point Tₘ and the like), the deposition thickness of the material, the width of the melt-extruded filaments or sintered powder and the like to achieve various in-situ heating effects of the printed article, such as softening, annealing, sintering and charring, so that the mechanical property of the 3D printed article is improved or its chemical structure is changed in situ in real time.

According to the present invention, the near-infrared semiconductor laser comprises a flexible optical fiber and an optical fiber head beam shaping system, wherein the optical fiber head beam shaping system comprises a beam collimating mirror and an adjustable attenuator, and the laser emitted by the near-infrared semiconductor laser is transmitted by the flexible optical fiber and is output from the adjustable attenuator after being collimated by the beam collimating mirror; the adjustable attenuator is used for adjusting the power density of the output laser.

According to the present invention, the near-infrared semiconductor laser further comprises a focusing system comprising a converging mirror disposed between the beam collimating mirror and the adjustable attenuator.

Preferably, the near-infrared semiconductor laser with a focusing system can be used for SLS high-precision printing and FDM high-precision heat treatment.

According to the present invention, an output wavelength of the near-infrared semiconductor laser is 0.78-2.5 μm (780-2500 nm), such as 808 nm, 850 nm, 940 nm, 1064 nm, 1200 nm, 1310 nm or 1550 nm.

According to the present invention, the power density of the near-infrared semiconductor laser is 0.1-10 kW/cm², such as 2-3 kW/cm², 0.1 kW/cm², 0.5 kW/cm², 1 kW/cm², 2 kW/cm², 3 kW/cm², 4 kW/cm², 5 kW/cm², 6 kW/cm², 7 kW/cm², 8 kW/cm², 9 kW/cm² or 10 kW/cm².

According to the present invention, the size of the spot formed by the near-infrared semiconductor laser may be adjusted according to the size of the printed article, and may be 1-1000 mm², such as 1 mm², 5 mm², 10 mm², 20 mm², 50 mm², 80 mm², 100 mm², 150 mm², 200 mm², 300 mm², 400 mm², 500 mm², 600 mm², 700 mm², 800 mm², 900 mm² or 1000 mm².

According to the present invention, the moving speed of the near-infrared semiconductor laser is 0.5-5 mm/s, such as 0.5 mm/s, 1 mm/s, 1.5 mm/s, 2 mm/s, 2.5 mm/s, 3 mm/s, 3.5 mm/s, 4 mm/s, 4.5 mm/s or 5 mm/s.

According to the present invention, the moving speed of the printing head of the 3D printing device is 10-40 mm/s, such as 10 mm/s, 15 mm/s, 20 mm/s, 25 mm/s, 30 mm/s, 35 mm/s or 40 mm/s.

According to the present invention, the 3D printing includes powder bed selective laser sintering (SLS) 3D printing, jet printing, direct ink writing (DIW) 3D printing, fused deposition modeling (FDM) 3D printing and the like.

According to the present invention, the 3D printing device is a device suitable for the above-mentioned 3D printing. For example, it may be an ink-jet 3D printer suitable for jet printing, or an extrusion 3D printer suitable for direct ink writing (DIW) 3D printing and fused deposition modeling (FDM) 3D printing, or a 3D printer suitable for powder bed selective laser sintering (SLS) 3D printing.

In the present invention, the near-infrared semiconductor laser has the characteristics of stable power, small size, transmission by a flexible quartz optical fiber, wide power regulation range, uniform energy distribution and the like, and can be bound with a software of any 3D printing device to realize continuous regulation of focal length of laser spot and output power of laser.

In the present invention, the material extruded or sprayed by the printing head of the 3D printing device or the material sintered by the laser-sintering printing head is heated by the near-infrared semiconductor laser, and the advantages are that:

(1) the laser is moved to carry out flexible local in-situ heating, and finally the heat treatment of the whole article is completed layer by layer, so that the interfaces of printed filaments or sintered powder is fused and eliminated and the residual internal stress is eliminated by the annealing of the material itself; however, if such an annealing effect is to be achieved using the existing commercial heating mode, machines will be high in cost, large in size and short in service life since the whole printing chamber is in a high temperature environment;

(2) the laser spot generated by the CO₂ gas laser working synchronously with the printing head must be focused on the extrusion or jet landing point of the printed filaments, so that the area of the spot is fixed, and the position of the spot is moved along with the printing head; however, the near-infrared semiconductor laser of the present application can be either coupled with the printing head or decoupled with the printing head, and therefore has higher flexibility;

(3) compared with the CO₂ gas laser, the near-infrared semiconductor laser has the characteristics of small size, low installation cost brought by flexible optical fiber transmission, better compatibility with various 3D printing devices and the like; and

(4) the near-infrared laser is mainly absorbed by sum-frequency vibration and multiple frequency vibration of molecules due to the interaction of light and substances, so that the near-infrared laser has higher penetration depth compared with 10.6-micron far-infrared laser generated by a CO₂ gas laser, which is not only beneficial to filament fusion in an in-plane (x-y plane), but also beneficial to filament fusion between layers (z direction).

Theoretically, with respect to the near-infrared laser, the diameter of a spot can be reduced from 50 μm of a CO₂ laser to 4-13 μm, and the reason is that the wavelength of the near-infrared laser is only 1/13-¼ of that of a CO₂ laser, that is, in principle, the spot focusing capacity can be increased by 4-13 times. Meanwhile, because the area is in square relation, it also means that the laser energy density is increased by 16-169 times under the same power, so that the processing characteristic of higher-power local sintering or heating with a smaller spot area is shown in SLS and FDM. That is, the near-infrared laser of the present invention has shorter wavelength and stronger focusing capability, and can realize higher printing precision (including higher precision of powder sintering in SLS and higher precision of local heat treatment processing in FDM) and higher energy density.

The present invention further provides a 3D printing system used for implementing the above-mentioned method, and the 3D printing system comprises a 3D printing device, a near-infrared semiconductor laser and a track, wherein

the 3D printing device comprises a printing head;

the near-infrared semiconductor laser comprises a flexible optical fiber and an optical fiber head beam shaping system, wherein the optical fiber head beam shaping system comprises a beam collimating mirror and an adjustable attenuator, and the laser emitted by the near-infrared semiconductor laser is transmitted by the flexible optical fiber and is output from the adjustable attenuator after being collimated by the beam collimating mirror;

the printing head and the near-infrared semiconductor laser are arranged on the same track or different tracks.

According to the present invention, the near-infrared semiconductor laser further comprises a focusing system comprising a converging mirror disposed between the beam collimating mirror and the adjustable attenuator.

Preferably, the near-infrared semiconductor laser with a focusing system can be used for SLS high-precision printing and FDM high-precision heat treatment.

The printing head may be a printing spray head (such as an extrusion type printing spray head, a jet type printing spray head) or a laser-sintering printing head.

The 3D printing device is a device suitable for the above-mentioned 3D printing. For example, it may be an ink-jet 3D printer suitable for jet printing, or an extrusion 3D printer suitable for direct ink writing (DIW) 3D printing and fused deposition modeling (FDM) 3D printing, or a 3D printer suitable for powder bed selective laser sintering (SLS) 3D printing.

The flexible optical fiber is, for example, a flexible quartz optical fiber.

Beneficial effects of the present invention:

The present invention provides a 3D printing method and a 3D printing system using a near-infrared semiconductor laser as a heating source. Compared with a heating source of a far-infrared CO₂ gas laser and a cavity heating source, the heating source of the near-infrared semiconductor laser has the characteristics of small size, adoption of flexible optical fiber transmission and the like; the near-infrared laser is characterized by higher penetration depth compared with a mid-infrared laser, so that the printing method can be flexibly compatible with various printing platforms, and the working process of the laser in the formed printing system can be decoupled from the 3D printing process of an article. Therefore, with a more flexible in-situ heating mode, it can simultaneously achieve the improvement of the interface bonding strength of multilayer extruded filaments or sintered powder and the elimination of the defects of mechanical properties and the structure of the article such as residual internal stress and low crystallinity. The 3D printing method and the printing system using the near-infrared semiconductor laser as the heating source of the present invention features low cost, high compatibility and high flexibility, and can replace the existing 3D printing working mode of cavity-assisted heating or CO₂ gas laser-assisted heating.

### BRIEF DESCRIPTION OF THE DRAWINGS

FIG. 1 shows a schematic diagram of same-track asynchronous control of the semiconductor laser and an extrusion 3D printer;

FIG. 2 shows a schematic diagram of double-track asynchronous control of the semiconductor laser and an extrusion 3D printer;

FIG. 3 shows an optical photograph of the bottom of a 1 mm article before and after laser treatment by the semiconductor laser in the same-track asynchronous mode;

FIG. 4 shows a scanning electron micrograph of heating process of the printed material by the semiconductor laser in the same-track asynchronous mode;

FIG. 5 shows the diagram of differential scanning calorimetry analysis before and after laser treatment of the printed material in the same-track asynchronous mode; and

FIG. 6 shows a diagram of mechanical tensile test results before and after laser treatment of the printed material in the same-track asynchronous mode.

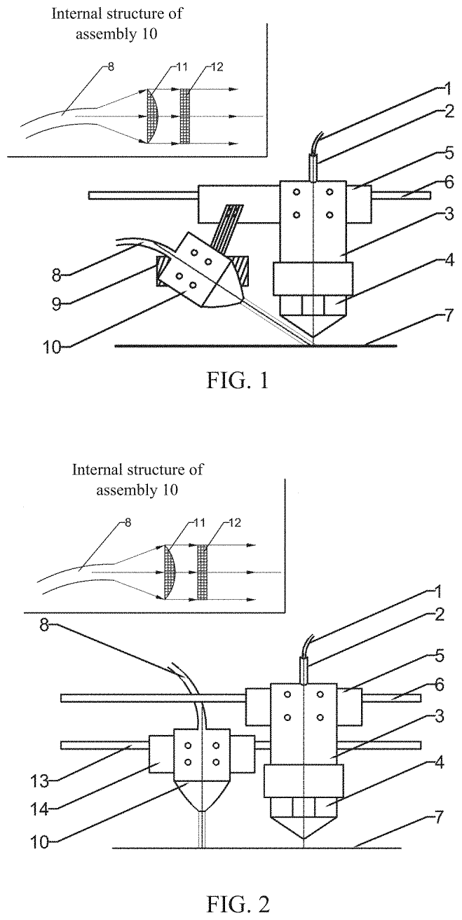

In FIGS. 1 and 2, 1 is a raw material filament, 2 is a sampler, 3 is a heating cylinder, 4 is a printing spray head, 5 is a first slide block, 6 is a first guide rail, 7 is a printing platform, 8 is a flexible quartz optical fiber, 9 is a detachable bracket, 10 is an optical fiber head beam shaping system, 11 is a beam collimating mirror, 12 is an adjustable attenuator, 13 is a second guide rail, and 14 is a second slide block.

### DETAILED DESCRIPTION

The preparation method of the present invention will be further illustrated in detail with reference to the following specific examples. It should be understood that the following examples are merely exemplary illustration and explanation of the present invention, and should not be construed as limiting the protection scope of the present invention. All techniques implemented based on the above-mentioned contents of the present invention are encompassed within the protection scope of the present invention.

Unless otherwise stated, the experimental methods used in the following examples are conventional methods. Unless otherwise stated, the reagents, materials, and the like used in the following examples are commercially available.

Instruments and Materials:

Polyetheretherketone filament (PEEK, available from Jilin JUSEP Special Plastics Co., Ltd.); experimental instruments comprise a desktop FDM 3D printer and an 808 nm near-infrared semiconductor laser; characterization instruments comprise a scanning electron microscope (JEOL JSM-7500F), a differential scanning calorimeter (TA Q-2000) and a universal tensile testing machine (UTM-16555, available from Shenzhen Suns Technology Stock Co., Ltd.).

The surface and cross section of the prepared sample are morphologically analyzed using a scanning electron microscope (SEM). The scanning electron microscope scans the surface of the sample through a tiny electron beam, and the secondary electrons generated in the scanning process are collected by a special detector. An electric signal is formed and then transmitted to the end of the image tube, then a three-dimensional structure of the surface of the object is displayed on a screen, and a computer is used for photographing. In this example, the ultra-high-resolution cold-field-emission scanning electron microscope JEOL JSM-7500F is employed with a accelerating voltage of 5 kV.

The processing thermal history of the prepared sample is analyzed by employing the differential scanning calorimeter (DSC) based on a power compensation principle of heat absorption and emission of material.

### Example 1

As shown in FIG. 1, a same-track asynchronous-controlled 3D printing system was provided, wherein a raw material filament 1 was fed into a heating cylinder 3 through a sampler 2, and a three-dimensional pattern was deposited layer by layer on a printing platform 7 through a printing spray head 4 under the three-axis movement of a first slide block 5 and a first guide rail 6; an optical fiber head beam shaping system 10 of a semiconductor laser was mounted on one side of the printing spray head 4 through a detachable bracket 9, so as to ensure that the output beam of the optical fiber head beam shaping system 10 can be accurately irradiated to a discharging position of the printing spray head 4, so that the output light can cover a fused deposition printing range of the original polymer material under the guidance of the movement of the first slide block 5, and meanwhile, the optical fiber head beam shaping system 10 of the semiconductor laser and the printing spray head 4 shared the first guide rail 6, resulting in vertical movement of the optical fiber head beam shaping system 10. The optical fiber head beam shaping system 10 comprised a beam collimating mirror 11 and an adjustable attenuator 12, which were used for collimating, converging and shaping the near-infrared laser transmitted by the flexible quartz optical fiber 8 and adjusting the power density.

In the printing process, after a single-layer or multi-layer polymer material was printed by using a slicing software, the sampler 2 stopped working, and then the first slide block 5 was started to guide the optical fiber head beam shaping system 10 to scan a printed area in an arbitrary path at a linear velocity of 1 mm/s for in-situ heating, thereby realizing the “same-track asynchronous” printing mode.

### Example 2

As shown in FIG. 2, a double-track asynchronously-controlled 3D printing system was provided, wherein an optical fiber head beam shaping system 10 of a semiconductor laser was mounted on a second slide block 14 through a second guide rail 13; a printing spray head 4 was mounted on a first guide rail 6 through a first slide block 5. The first slide block 5 and the second slide block 14 had the same function and both can move in a plane; the first guide rail 6 and the second guide rail 13 had the same function and both can move vertically.

In the printing process, after a single-layer or multi-layer polymer material was printed by the printing spray head 4, the second guide rail 13 and the second slide block 14 were controlled by a slicing software to guide the laser to scan a printed area in an arbitrary path at a linear velocity of 1 mm/s for in-situ heating, thereby realizing the “double-track asynchronous” printing mode.

### Test Example 1

The annealing effect of the printed material with single-layer, double-layer or five-layer deposition thickness after in-situ heating with the semiconductor laser, the interface bonding strength among filaments of a printed article and the enhancement effect of the macroscopic mechanical property in the same-track asynchronous control mode of Example 1 and in the double-track asynchronous control mode of Example 2 were tested.

The geometrical parameters and laser processing conditions of the processed FDM-printed articles are shown in the following table.

| Type of | | | |
|---|---|---|---|
| article | Shape | Thickness | Laser condition |
| Single- | Rectangle, 1 cm × | 0.4 mm | Collimated beam, circular spot, |
| layer | 5 cm | | power density 2.0 kW/cm² |
| Double- | Rectangle, 1 cm × | 0.6 mm | Collimated beam, circular spot, |
| layer | 5 cm | | power density 2.0 kW/cm² |
| Five-layer | Rectangle, 1 cm × | 1 mm | Collimated beam, circular spot, |
| | 5 cm | | power density 3.0 kW/cm² |

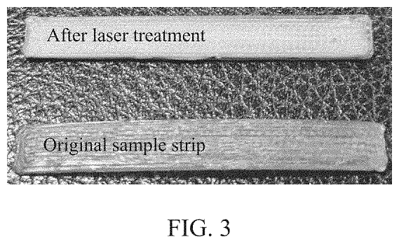

Referring to FIG. 3, compared with an original FDM-printed sample strip with the same five-layer deposition thickness, the printed sample strip which was heated in situ by using an 808 nm semiconductor laser at an output power density of 3.0 kW/cm′ in two control modes (same-track asynchronous mode in Example 1 and double-track asynchronous mode in Example 2) had an obviously whitish color at its bottom, and the whole article had volume shrinkage, which showed that the 1 mm thickness of the article had no influence on the in-situ heating of the whole article with the 808 nm semiconductor laser, indicating that the 808 nm semiconductor laser had higher penetration depth.

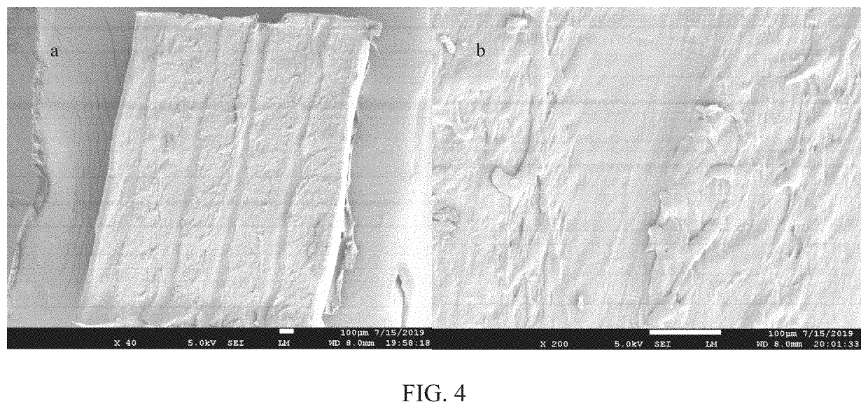

Referring to FIG. 4, a and b in the scanning electron micrograph (FIG. 4) showed that after heated in situ by the 808 nm semiconductor laser in two control modes, the single-layer printed sample strip exhibited interface fusion of melt-extruded filaments in an in-plane direction (x-y plane), which indicates that the in-situ heating using the 808 nm semiconductor laser in the two control modes had an obvious enhancement effect on the interface bonding strength of the 3D printing extruded filaments, and the influence of weak interface bonding strength among FDM-printed filaments on the macroscopic mechanical property can be weakened.

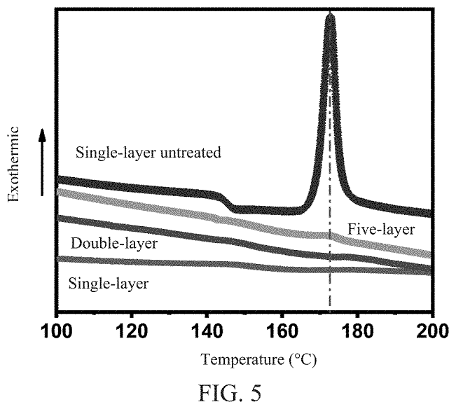

Referring to FIG. 5, after the printed articles with single-layer, double-layer or five-layer deposition thickness were heated in-situ by using the 808 nm semiconductor laser in two control modes, secondary crystallization peaks of printed articles of all deposition thickness at about 173° C. disappeared, i.e. realizing annealing treatment. By integrating the exothermic peaks around the temperature, the annealing efficiency of the single-layer and double-layer printed articles was 100% and the annealing efficiency of the five-layer printed article was 98.7%, which indicated that the crystallinity of all articles was improved after in-situ heating and tended to the intrinsic value of the material, further resulting in whitening of the articles caused by the enhanced birefringence phenomenon and volume shrinkage caused by the increase of density, which is consistent with the macroscopic phenomenon described in FIG. 3.

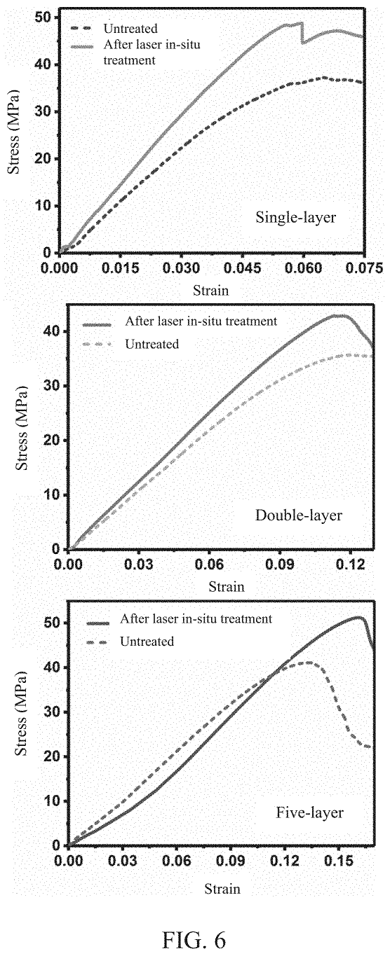

Referring to a-c in FIG. 6, after in-situ heating using the 808 nm semiconductor laser in two control modes, in addition to the qualitative phenomenon of whitening, volume shrinkage and the improvement of mechanical properties such as the enhancement of interface bonding strength, tensile mechanical tests showed that the overall tensile breaking strength of all articles after in-situ heating was improved by about 30%. Compared with the sample strip without in-situ heating, the single-layer sample strip had an increased tensile breaking strength from 37 MPa to 49 MPa, an increase of 32.4%; the double-layer sample strip had an increased tensile breaking strength from 35 MPa to 43 MPa, an increase of 23.0%; the five-layer sample strip had an increased tensile breaking strength from 41 MPa to 52 MPa, an increase of 27.0%.

The results showed that through in-situ heating of the FDM-printed articles by using the 808 nm semiconductor laser in two control modes, the processing thermal history of the printed articles can be obviously eliminated so that the crystallization was more perfect and tended to the intrinsic status, and the bonding strength among extruded filaments can be enhanced through interface fusion so that the printed articles were more compact at the macro level, and the tensile breaking strength of the articles was increased by about 30%.

### Example 3

A double-track asynchronously-controlled 3D printing system was provided, which was substantially the same as that of Example 2, except that the semiconductor laser of Example 3 further comprised a focusing system comprising a converging mirror disposed between a beam collimating mirror and an adjustable attenuator. The 3D printing system of Example 3 employed SLS high-precision printing.

### Example 4

A double-track asynchronously-controlled 3D printing system was provided, which was substantially the same as that of Example 2, except that the semiconductor laser of Example 4 further comprised a focusing system comprising a converging mirror disposed between a beam collimating mirror and an adjustable attenuator. The 3D printing system of Example 4 employed FDM high-precision printing.

Since line (dot) resolution of less than 0.1 mm is usually required for SLS and FDM high-precision printing, the focus projection distance (generally, centimeter-level or more) from the laser to the printed article is far greater than the image size of the convergent spot, which approximates the Fraunhofer Diffraction. According to rayleigh criterion of diffraction limit (formula 1, wherein x is minimum imaging distance (resolution), f is focal length, λ is laser wavelength, and D is converging mirror diameter), under the condition that the structure size of the 3D printing device and the laser is fixed, the minimum imaging distance x of the laser spot reduces along with the reduction of the wavelength, that is, the resolution of the laser scanning path increases along with the reduction of the wavelength. Therefore, compared with a CO₂ laser adopting far-infrared wavelength, the near-infrared semiconductor laser of the present invention can realize laser scanning with higher precision, and further meet the requirements for preparing SLS-printed and FDM-printed articles with higher precision.

$$x = \frac{1.22 λ f}{D} \qquad ( 1 )$$

The examples of the present invention have been described above. However, the present invention is not limited to the above examples. Any modification, equivalent, improvement and the like made within the spirit and principle of the present invention shall fall within the protection scope of the present invention.

1. A 3D printing method, characterized in that a near-infrared semiconductor laser is used as a heating source, that is, a laser beam generated by the laser is used for in-situ heating of an article in a 3D printing process.

2. The method according to claim 1, wherein the method employs a 3D printing device using a near-infrared semiconductor laser as a heating source to perform the 3D printing in an “asynchronous” mode;
preferably, the 3D printing device comprises a printing head; in the 3D printing process, the laser beam (such as a collimated beam) is output by the near-infrared semiconductor laser to form a laser spot, which scans in an arbitrary path to cover a relevant area of a printed material for in-situ heating, thereby realizing “asynchronous” printing mode.

3. The method according to claim 1, wherein the method comprises:
performing 3D printing by using a 3D printing device with the near-infrared semiconductor laser as the heating source, wherein in the printing process, the laser output by the near-infrared semiconductor laser realizes flexible optical fiber transmission through spatial coupling, and a collimated beam is output through an optical fiber head beam shaping system of the near-infrared semiconductor laser to form a laser spot, which scans in an arbitrary path to cover a relevant area of the printed material for in-situ heating of an article, thereby realizing “asynchronous” printing mode in the 3D printing process.

4. The method according to claim 1, wherein the method comprises:
performing 3D printing by using a 3D printing device with the near-infrared semiconductor laser as the heating source, wherein in the printing process, the near-infrared semiconductor laser and a printing head are separately controlled by double tracks, and the printing head is used to print single-layer or multi-layer materials. The laser output by the near-infrared semiconductor laser realizes flexible optical fiber transmission through spatial coupling, and a collimated beam is output by an optical fiber head beam shaping system of the near-infrared semiconductor laser to form a laser spot, which scans in an arbitrary path to cover a relevant area of the printed material for in-situ heating. The process is repeated for multiple times to realize “double-track asynchronous” printing mode of an article in the 3D printing process.

5. The method according to claim 1, wherein the method comprises:
performing 3D printing by using a 3D printing device with the near-infrared semiconductor laser as the heating source, wherein in the printing process, the near-infrared semiconductor laser and a printing head are controlled by the same track and first the printing head is used to print single-layer or multi-layer materials; then the printing is suspended, and the laser output by the near-infrared semiconductor laser realizes flexible optical fiber transmission through spatial coupling, and a collimated beam is output by an optical fiber head beam shaping system of the near-infrared semiconductor laser to form a laser spot, which scans in an arbitrary path to cover a relevant area of the printed material for in-situ heating. The process is repeated for multiple times to realize “same-track asynchronous” printing mode of an article in the 3D printing process.

6. The method according to claim 1, wherein the near-infrared semiconductor laser comprises a flexible optical fiber and an optical fiber head beam shaping system, wherein the optical fiber head beam shaping system comprises a beam collimating mirror and an adjustable attenuator, and the laser emitted by the near-infrared semiconductor laser is transmitted by the flexible optical fiber and is output from the adjustable attenuator after being collimated by the beam collimating mirror; the adjustable attenuator is used for adjusting the power density of the output laser.

7. The method according to claim 6, wherein the near-infrared semiconductor laser further comprises a focusing system comprising a converging mirror disposed between the beam collimating mirror and the adjustable attenuator.

8. The method according to claim 1, wherein an output wavelength of the near-infrared semiconductor laser is 780-2500 nm; and/or
a power density of the near-infrared semiconductor laser is 0.1-10 kW/cm²; and/or
a size of the spot formed by the near-infrared semiconductor laser is 1-1000 mm²; and/or
a moving speed of the near-infrared semiconductor laser is 0.5-5 mm/s; and/or
a moving speed of the printing head of the 3D printing device is 10-40 mm/s.

9. The method according to claim 1, wherein the 3D printing includes powder bed selective laser sintering (SLS) 3D printing, jet printing, direct ink writing (DIW) 3D printing or fused deposition modeling (FDM) 3D printing.

10. A 3D printing system, wherein the 3D printing system is used for implementing the method according to claim 1 and comprises a 3D printing device, a near-infrared semiconductor laser and a track, wherein
the 3D printing device comprises a printing head;
the near-infrared semiconductor laser comprises a flexible optical fiber and an optical fiber head beam shaping system, wherein the optical fiber head beam shaping system comprises a beam collimating mirror and an adjustable attenuator, and the laser emitted by the near-infrared semiconductor laser is transmitted by the flexible optical fiber and is output from the adjustable attenuator after being collimated by the beam collimating mirror;
the printing head and the near-infrared semiconductor laser are arranged on the same track or different tracks;
preferably, the near-infrared semiconductor laser further comprises a focusing system comprising a converging mirror disposed between the beam collimating mirror and the adjustable attenuator.
